(19) United States
(12) Patent Application Publication
(10) Pub. No.: US 2006/0260547 A1
(43) Pub. Date: Nov. 23, 2006

(54) Apparatus for coating substrates on both sides

(75) Inventors: Walter Zultzke, Maintal (DE); Markus Fuhr, Eppstein (DE)

Correspondence Address: LERNER GREENBERG STEMER LLP, P O BOX 2480, HOLLYWOOD, FL, 33022-2480, US

(73) Assignee: Leybold Optics GmbH

(21) Appl. No.: 11/254,388

(22) Filed: Oct. 20, 2005

(30) Foreign Application Priority Data
May 20, 2005 (DE) 20 2005 008 165.5

(51) Int. Cl. C23C 16/00

(52) U.S. Cl. 118/726

(57) ABSTRACT

An apparatus for the vapor deposition of a layer, in particular of a hydrophobic and/or oleophobic top coat layer, onto front and rear sides of planar substrates. The apparatus includes at least one vacuum chamber. A substrate holder is disposed in said vacuum chamber for receiving at least one substrate. A first evaporator is disposed in said vacuum chamber opposite the front side of the substrate. At least one second evaporator is disposed in said vacuum chamber opposite the rear side of the substrate. The second evaporator has a radiation plate for directing evaporated material in direction of the substrate and a basket-like wire container disposed between said substrate holder and said radiation plate, for receiving at least one pellet with material to be evaporated in said wire container.

### BACKGROUND OF THE INVENTION

1. Field of the Invention

The invention relates to an apparatus for the vapor deposition of a layer, in particular of a hydrophobic and/or oleophobic top coat layer, onto a front and a rear side of planar substrates.

Antisoiling, in particular hydrophobic and/or oleophobic, top coat layers for reducing water stains and soil adhesion on optical substrates, such as eyeglass lenses, for example, are known. Thus, German Published, Non-Prosecuted Patent Application DE 37 01 654 A1, corresponding to Japanese Patents JP62178902, JP62178903, JP62247302, JP62169102, JP5341107 and JP7098414, describes treating articles coated with silicon oxide, such as lenses, display panels and the like, with a material which produces a water-repellent effect after reaction or absorption at the surface to be treated. In the case of eyeglass lenses, the top coat layer is usually applied on antireflection layers, but top coat layers on plastic lenses provided only with a hard coating or uncoated mineral glasses are also known.

Optical lenses provided with a top coat layer, as are used in eyeglasses, for example, are nowadays produced in industrial process installations in which, before the top coat layer is produced, usually the lens is shaped and cleaned, a hard coat is applied by dip-coating or spin-coating, drying and heat treatment are effected before application of an antireflection layer and, as a final step, the coating with the hydrophobic and olephobic top coat layer is effected. As an alternative, it is customary to also produce the hard coat through the use of a PECVD process and the antireflection layer through the use of sputtering.

A method of applying a thin water-repellent and oil-repellent layer on a silicon oxide coating with antireflective properties can be gathered from U.S. Patent Application Publication No. US 2004/0142185 A1. That publication proposes using, as the evaporation source for a hydrophobic reactive organic component, a porous ceramic matrix impregnated with the hydrophobic reactive component or a block of metal fibers.

German Published, Non-Prosecuted Patent Application DE 44 30 363 A1, corresponding to Canadian Patent No. 2,157,070, discloses a vacuum coating installation in which an antiscratch layer and optical layers are vapor-deposited onto optical substrates through the use of an electron beam evaporator with simultaneous action of a plasma or ion beam.

In that case, the material for the coating is evaporated by the electron beam evaporator and passes through the plasma or ion beam directed onto the substrate, with the material being activated. A hydrophobic layer made of TMDS is vapor-deposited as a covering layer. In that case, the substrates are disposed on a spherical cap and mounted in spring rings, for example. If the front and rear sides of the substrate are intended to be coated, the substrate has to be turned. For that purpose, the spherical cap may be embodied, for example, in such a way that individual segments of the spherical cap can be rotated about their axis and the rear side of the substrate can be coated after turning.

The disadvantage of that installation is that the hydrophobic effect of the top coat layer applied last to the front side is partly eliminated again by the coating of the rear side, in particular by the action of ions.

### SUMMARY OF THE INVENTION

It is accordingly an object of the invention to provide an apparatus for coating substrates on both sides, which overcomes the hereinafore-mentioned disadvantages of the heretofore-known apparatuses of this general type and which can be used to produce a top coat layer on both sides of a substrate in a simple, reliable and cost-effective manner.

With the foregoing and other objects in view there is provided, in accordance with the invention, an apparatus for the vapor deposition of a layer, in particular of a hydrophobic and/or oloephobic top coat layer, onto a front and a rear side of planar substrates, comprising at least one vacuum chamber with a substrate holder for receiving at least one substrate, a first evaporator disposed opposite the front side of the substrate, and a second evaporator disposed opposite the rear side of the substrate. In this case, at least the second evaporator is formed as a basket-type wire container and the wire container is disposed between the substrate holder and a radiation plate. Evaporated material which can emerge from the wire container in all directions is directed or can be directed in the direction of the substrate through the use of the radiation plate. At least one pellet with the material to be evaporated is disposed or can be disposed in the wire container. The wire container is formed, in particular, of metal wire having a high melting point, for example tungsten, and the wire container is formed in such a way that the pellet cannot fall out.

In accordance with another feature of the invention, the wire container is heated and preferably concomitantly heats the radiation plate through the use of radiant heat and/or the radiation plate can be heated separately, thereby preventing condensation of the coating material on the radiation plate.

Metal plates of molybdenum, tantalum, tungsten, copper and/or high-grade steel may preferably be used as the radiation plate. However, it is also possible to use materials such as ceramic or graphite.

In accordance with a further feature of the invention, the coating material to be evaporated is incorporated in the cavities of the pellet formed of a porous material. The porous material is preferably inert, that is to say no reaction takes place between the porous material of the pellet and the coating material. The porous material has its melting and boiling point significantly above the evaporation temperature of the coating material and preferably is formed of pressed aluminum oxide (Al₂O₃), a sintering metal and/or metal chips.

In accordance with still a further feature of the invention, the second evaporator is disposed above the substrate holder, so that substrates disposed in the substrate holder can be coated on both sides without having to be turned, preferably also simultaneously from both sides, with a top coat layer.

In accordance with an additional feature of the invention, the first evaporator is likewise formed as a wire container with a radiation plate. The radiation plate is preferably disposed in the wire container and the pellet is disposed or can be disposed on the radiation plate.

In accordance with yet another feature of the invention, disposed alongside the first evaporator for evaporating the top coat layer that is to be applied as the last layer to the substrate on both sides, may be a further evaporator, for example an electron beam evaporator, and, if appropriate, a plasma or ion beam source below the substrate holder. As a result, functional layers, for example antireflection layers, can be vapor-deposited onto the substrate on one side, if appropriate with the action of a plasma or ion beam, before the top coat layer is applied on both sides.

In accordance with yet a further feature of the invention, if the functional layers are intended to be applied to the substrate on both sides, the substrate holder may preferably be trapezoidal segments of a spherical cap which can be rotated about their longitudinal axis and through the use of which the substrates can be turned within the vacuum chamber. Alternatively, the substrate holder may be embodied as a turnable paddle.

In accordance with a concomitant feature of the invention, the wire container is formed as a helix, in particular as a conical helix. This embodiment permits a simple fixed mount and a simple exchange of the pellet with the material to be evaporated and enables the evaporated material to emerge unimpeded.

Other features which are considered as characteristic for the invention are set forth in the appended claims.

Although the invention is illustrated and described herein as embodied in an apparatus for coating substrates on both sides, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, partly-sectional and partly-elevational view of an apparatus according to the invention;

FIG. 2 is a fragmentary, elevational view of a second evaporator for coating from above; and

FIG. 3 is a view similar to FIG. 2 of a first evaporator for coating from below.

### DESCRIPTION OF THE PREFERRED EMBODIMENTS

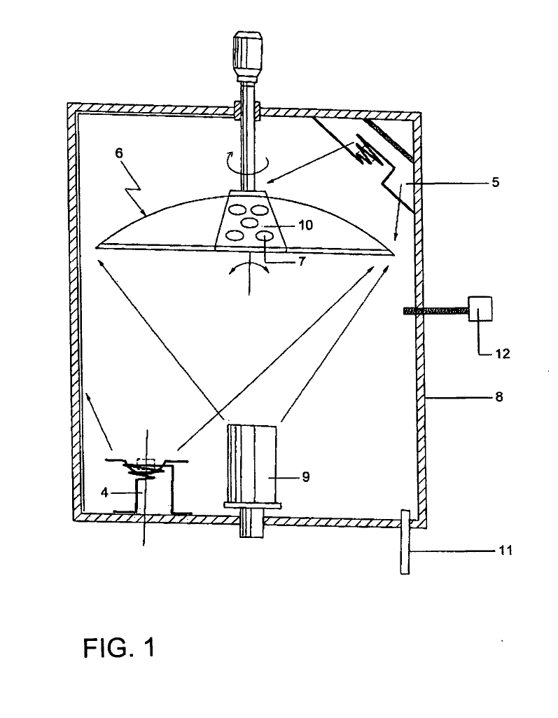

Referring now to the figures of the drawings in detail and first, particularly, to FIG. 1 thereof, there is seen a diagrammatic illustration of an apparatus according to the invention for the vapor deposition of a hydrophobic top coat layer onto a substrate 7 on both sides. Functional layers can be applied to the substrate 7 through the use of the apparatus before the vapor deposition of the hydrophobic coating.

The apparatus illustrated in FIG. 1 is a vacuum coating installation, including a vacuum chamber 8 with a substrate holder 6 in the form of a spherical cap, a first evaporator 4, a second evaporator 5 and a plasma source 9.

The substrate holder 6, which is in the form of a spherical cap, includes individual trapezoidal segments 10 on which the substrates 7 are disposed. The segments 10 can be rotated about their longitudinal axis for the purpose of turning the substrates 7. The substrates 7 are mounted in the segments through the use of spring rings, for example.

In order to apply a functional layer to one side of the substrates 7, a plasma beam is generated through the use of the plasma source 9 and a monomer with layer-forming substances is introduced into the plasma beam through a gas inlet 11. In addition or as an alternative, it is also possible for functional layers to be vapor-deposited through the use of the first evaporator 4 or through the use of a non-illustrated electron beam evaporator.

In order to coat the other side of the substrates 7 with one or more functional layers, they are turned by rotation of the segments 10 and coated in the manner described above.

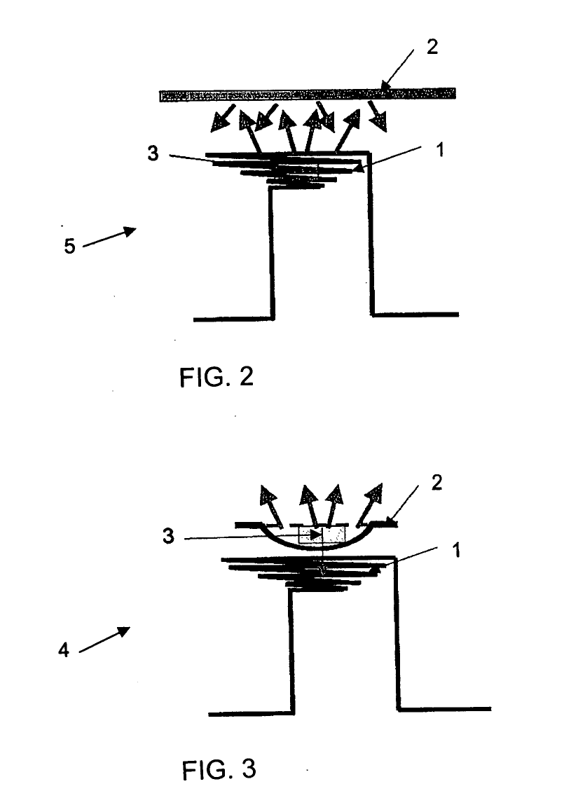

The concluding coating of the substrates 7 with a hydrophobic top coat layer on both sides is effected through the use of the first evaporator 4, which is illustrated in detail in FIG. 3, and through the use of the second evaporator 5, which is illustrated in detail in FIG. 2. In this case, the front and rear sides of the substrates 7 may be coated simultaneously by evaporating coating material from below through the use of the first evaporator 4 disposed below the substrate holder 6, and evaporating coating material from above through the use of the second evaporator 5 disposed above the substrate holder 6. A uniform layer thickness distribution may be obtained in this case through the use of a suitable position of the first evaporator 4 and of the second evaporator 5 as well as through the admission of scattering gas, for example argon, through a scattering gas inlet 12.

The second evaporator 5 illustrated in FIG. 2 is disposed above the substrate holder 6 and evaporates the coating material for the hydrophobic top coat layer from above. For this purpose, the second evaporator 5 includes a radiation plate 2, and a heatable helix 1 made of tungsten, which tapers toward the lower end like a basket-like wire container. A pellet 3 with the material to be evaporated can be inserted into the conically formed helix 1. In this case, the heated helix 1 likewise heats the radiation plate 2, which is disposed closely above the helix 1 and which directs the evaporated material emerging in all directions in the direction of the substrates 7.

The first evaporator 4 illustrated in FIG. 3 is disposed below the substrate holder 6 and evaporates the coating material for the hydrophobic top coat layer from below. For this purpose, the first evaporator 4 likewise includes a heatable helix 1 made of tungsten and a radiation plate 2. In this case, the radiation plate 2 is formed in the shape of a shell, is inserted into the upwardly widening opening of the helix 1 and is heated by the helix 1. The pellet 3 with the material to be evaporated is inserted into the radiation plate 2, with the evaporated material being directed in the direction of the substrates 7 by the radiation plate.

This application claims the priority under 35 U.S.C. §119, of German utility model No. 20 2005 008 165, filed May 20, 2005; the entire disclosure of the prior application is herewith incorporated by reference.

We claim:

1. An apparatus for the vapor deposition of a layer onto front and rear sides of planar substrates, the apparatus comprising:
at least one vacuum chamber;
a substrate holder disposed in said at least one vacuum chamber for receiving at least one substrate;
a first evaporator disposed in said at least one vacuum chamber opposite the front side of the at least one substrate; and
at least one second evaporator disposed in said at least one vacuum chamber opposite the rear side of the at least one substrate, said at least one second evaporator having a radiation plate for directing evaporated material in direction of the at least one substrate, and said at least one second evaporator having a basket-like wire container disposed between said substrate holder and said radiation plate, for receiving at least one pellet with material to be evaporated in said wire container.

2. The apparatus according to claim 1, wherein said first evaporator is disposed geodetically below said substrate holder and said second evaporator is disposed geodetically above said substrate holder.

3. The apparatus according to claim 2, wherein said first evaporator has a basket-type wire container and a radiation plate.

4. The apparatus according to claim 3, wherein said radiation plate of said first evaporator is disposed in said wire container of said first evaporator, and said radiation plate of said first evaporator is for receiving at least one pellet with the material to be evaporated.

5. The apparatus according to claim 1, wherein said wire container of said at least one second evaporator is formed of metal wire having a high melting point.

6. The apparatus according to claim 3, wherein said wire container of said first evaporator is formed of metal wire having a high melting point.

7. The apparatus according to claim 5, wherein said metal wire is formed of a metal selected from the group consisting of tungsten, molybdenum and tantalum.

8. The apparatus according to claim 6, wherein said metal wire is formed of a metal selected from the group consisting of tungsten, molybdenum and tantalum.

9. The apparatus according to claim 1, wherein said wire container of said at least one second evaporator is formed as a helix.

10. The apparatus according to claim 3, wherein said wire container of said first evaporator is formed as a helix.

11. The apparatus according to claim 9, wherein said helix is a conical helix.

12. The apparatus according to claim 10, wherein said helix is a conical helix.

13. The apparatus according to claim 1, wherein the pellet in said basket-type wire container is formed of a porous material having cavities in which the material to be evaporated is incorporated.

14. The apparatus according to claim 4, wherein the pellet in said radiation plate is formed of a porous material having cavities in which the material to be evaporated is incorporated.

15. The apparatus according to claim 1, wherein said radiation plate of said at least one second evaporator is formed of at least one material selected from the group consisting of molybdenum, tantalum, tungsten, copper and high-grade steel.

16. The apparatus according to claim 3, wherein said radiation plate of said first evaporator is formed of at least one material selected from the group consisting of molybdenum, tantalum, tungsten, copper and high-grade steel.

17. The apparatus according to claim 1, wherein said radiation plate of said at least one second evaporator is heatable.

18. The apparatus according to claim 3, wherein said radiation plate of said first evaporator is heatable.

19. The apparatus according to claim 1, wherein said substrate holder is a spherical cap for receiving a plurality of substrates.

20. An apparatus for the vapor deposition of at least one of a hydrophobic or oleophobic top coat layer onto front and rear sides of planar substrates, the apparatus comprising:
at least one vacuum chamber;
a substrate holder disposed in said at least one vacuum chamber for receiving at least one substrate;
a first evaporator disposed in said at least one vacuum chamber opposite the front side of the at least one substrate; and
at least one second evaporator disposed in said at least one vacuum chamber opposite the rear side of the at least one substrate, said at least one second evaporator having a radiation plate for directing evaporated hydrophobic or oleophobic material in direction of the at least one substrate, and said at least one second evaporator having a basket-like wire container disposed between said substrate holder and said radiation plate, for receiving at least one pellet with hydrophobic or oleophobic material to be evaporated in said wire container.
